(19) United States
(12) Patent Application Publication
(10) Pub. No.: US 2026/0190382 A1
(43) Pub. Date: Jul. 2, 2026

(54) HIGH VOLTAGE SEMICONDUCTOR DEVICES

(71) Applicant: Samsung Electronics Co., Ltd., Suwon-si (KR)

(72) Inventors: Hiroki FUJII, Suwon-si (KR); Jaehyun YOO, Suwon-si (KR); Dawon JEONG, Suwon-si (KR); Kunsik SUNG, Suwon-si (KR)

(73) Assignee: Samsung Electronics Co., Ltd., Suwon-si (KR)

(21) Appl. No.: 19/425,081

(22) Filed: Dec. 18, 2025

(30) Foreign Application Priority Data
Dec. 26, 2024 (KR) 10-2024-0197453

(51) Int. Cl. H10D 30/65; H10D 30/01; H10D 64/00

(52) U.S. Cl. CPC H10D 30/658; H10D 30/0289; H10D 64/111

(57) ABSTRACT

A high voltage semiconductor device includes a substrate, a well region of a first conductivity-type within the substrate, first and second drift regions of a second conductivity-type in the well region, a gate trench including a bottom between the first and second drift regions, the bottom partially defining the well region, and first and second sidewalls facing each other, the first sidewall and the second sidewall partially defining the first drift region and the second drift region, respectively, a gate insulating film covering the bottom, the first sidewall, and the second sidewall of the gate trench, a gate electrode buried in a lower region of the gate trench, and a field distribution structure disposed on the gate electrode in an upper region of the gate trench, and extending higher than an upper surface of the first drift region and an upper surface of the second drift region.

### CROSS-REFERENCE TO RELATED APPLICATION(S)

This application claims the benefit under 35 USC 119(a) of Korean Patent Application No. 10-2024-0197453 filed on Dec. 26, 2024 in the Korean Intellectual Property Office, the entire disclosure of which is incorporated herein by reference for all purposes.

### BACKGROUND

Example embodiments of the present inventive concepts relate to high voltage semiconductor devices.

In general, high voltage semiconductor devices are widely used in various integrated circuits such as nonvolatile memory or display driver ICs (DDIs). For example, high voltage semiconductor devices may include high voltage transistors having recessed trench channels, and may be used together with transistors (for example, transistors having flat channels) that may have different operating voltages and/or functions.

In detail, methods for securing electrical characteristics such as high breakdown voltage and/or low Gate Induced Drain Leakage (GIDL) of the impurity regions forming the source/drain for high voltage transistors having recessed channels have been studied.

### SUMMARY

Some example embodiments provide a high voltage semiconductor device having improved electrical characteristics.

According to some example embodiments, a high voltage semiconductor device includes a substrate, a well region of a first conductivity-type within the substrate, a first drift region and second drift region of a second conductivity-type in the well region, a gate trench including a bottom between the first drift region and the second drift region, the bottom partially defining the well region, and a first sidewall and a second sidewall facing each other, the first sidewall and the second sidewall partially defining the first drift region and the second drift region, respectively, a gate insulating film covering the bottom, the first sidewall, and the second sidewall of the gate trench, a gate electrode buried in a lower region of the gate trench, and a field distribution structure disposed on the gate electrode in an upper region of the gate trench, and extending higher than an upper surface of the first drift region and an upper surface of the second drift region.

According to some example embodiments, a high voltage semiconductor device includes a substrate, a well region of a first conductivity-type within the substrate, a first drift region and a second drift region of a second conductivity-type arranged in the well region in a first direction, a gate trench extending in a second direction between the first drift region and the second drift region, the second direction intersecting the first direction, and the gate trench including a bottom partially defining the well region, and a first sidewall and a second sidewall facing each other, the first sidewall and the second sidewall partially defining the first drift region and the second drift region, respectively, a gate insulating film covering the bottom, the first sidewall, and the second sidewall of the gate trench, a gate electrode buried in a lower region of the gate trench and extending in the second direction, an interlayer insulating layer on the substrate and covering the first drift region, the second drift region, and the gate electrode, a first contact plug and a second contact plug penetrating the interlayer insulating layer and connected to the first drift region and the second drift region, respectively, and a field distribution structure penetrating the interlayer insulating layer, and extending in the second direction on the gate electrode, the field distribution structure including a same material as a material of the first contact plug and a material of the second contact plug.

According to some example embodiments, a high voltage semiconductor device includes a substrate, a well region of a first conductivity-type within the substrate, a first drift region and a second drift region of a second conductivity-type arranged in the well region in a first direction, a gate trench extending in a second direction between the first drift region and the second drift region, the second direction intersecting the first direction, and the gate trench including a bottom partially defining the well region, and a first sidewall and a second sidewall facing each other, the first sidewall and the second sidewall partially defining the first drift region and second drift region, respectively, a gate insulating film covering the bottom, the first sidewall, and the second sidewall of the gate trench, a gate electrode buried in a lower region of the gate trench and extending in the second direction, a field distribution structure extending in the second direction on the gate electrode and having an upper surface higher than an upper surface of the first drift region and an upper surface of the second drift region, the field distribution structure including a same material as a material of the gate electrode, an interlayer insulating layer on the substrate and covering the first drift region, the second drift region, the gate electrode, and the field distribution structure, and a first contact plug and a second contact plug penetrating the interlayer insulating layer and respectively connected to the first drift region and the second drift region.

According to some example embodiments, a method of manufacturing a high voltage semiconductor device includes forming a well region on a first region and a second region of a semiconductor substrate, the well region including a first conductivity-type, forming a device isolation region in the well region, the device isolation region defining an active region, forming a first drift region and a second drift region in the first region and the second region, respectively, forming a gate trench in the first region using a first photoresist pattern, forming a channel region under the gate trench in the first region using an ion implantation process, removing the first photoresist pattern, forming a gate insulating film in the first region and the second region covering inner surfaces of the gate trench, the device isolation region, the well region, the first drift region, and the second drift region, forming a conductive material layer on the gate insulating film, the conductive material layer at least partially filling the gate trench, forming a second photoresist pattern on the conductive material layer in the second region, performing an etch-back process to form a first gate electrode and a second gate electrode in the first region and the second region, respectively, forming a gate spacer on sidewalls of the second gate electrode in the second region, and on inner sidewalls of the gate trench in the first region, and forming an interlayer insulating layer covering the device isolation region, the well region, the first drift region, the second drift region, and the first and second gate electrodes.

According to some example embodiments, the method of manufacturing the high voltage semiconductor device further includes forming contact holes in the interlayer insulating layer in the first region and the second region, the contact holes exposing the first drift region, the second drift region, the first gate electrode and the second gate electrode, and forming a field distribution structure contacting the first gate electrode and the second gate electrode, and forming a first and second contact plug contacting the first drift region the second drift region, respectively.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view illustrating a high voltage semiconductor device according to some example embodiments;

FIG. 2 is a cross-sectional side view taken along line I-I′ of the high voltage semiconductor device illustrated in FIG. 1;

FIG. 3 is a partially enlarged view illustrating a portion A1 of the high voltage semiconductor device illustrated in FIG. 2;

FIGS. 4A to 4C are schematic diagrams illustrating impact ionization in high voltage semiconductor devices having various gate structures (Comparative Examples 1, 2, and an example embodiment);

FIGS. 5A to 5C are schematic diagrams illustrating band-to-band generation distribution of carrier in high voltage semiconductor devices having various gate structures (Comparative Examples 1, 2, and an example embodiment);

FIG. 6 illustrates I-V curves of high voltage semiconductor devices according to Comparative Examples 1, 2, and an example embodiment;

FIGS. 7A to 7I are cross-sectional views of major processes, illustrating a method of manufacturing a high voltage semiconductor device according to some example embodiments;

FIGS. 8 and 9 are plan and side cross-sectional views of a high voltage semiconductor device according to some example embodiments, respectively;

FIGS. 10 and 11 are plan and side cross-sectional views of a high voltage semiconductor device according to some example embodiments, respectively;

FIG. 12 is a partially enlarged view illustrating a portion A2 of the high voltage semiconductor device illustrated in FIG. 11; and

FIGS. 13A to 13D are cross-sectional views of major processes, illustrating a method of manufacturing a high voltage semiconductor device according to some example embodiments.

### DETAILED DESCRIPTION

Hereinafter, some example embodiments will be described with reference to the accompanying drawings.

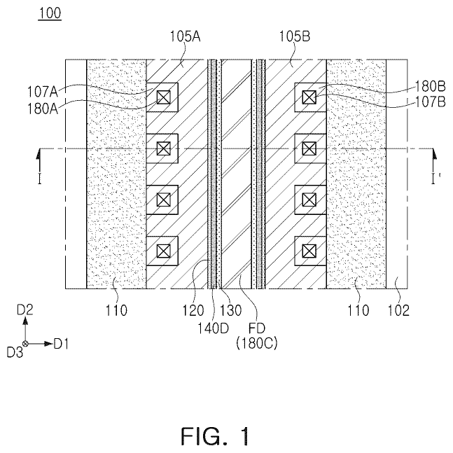

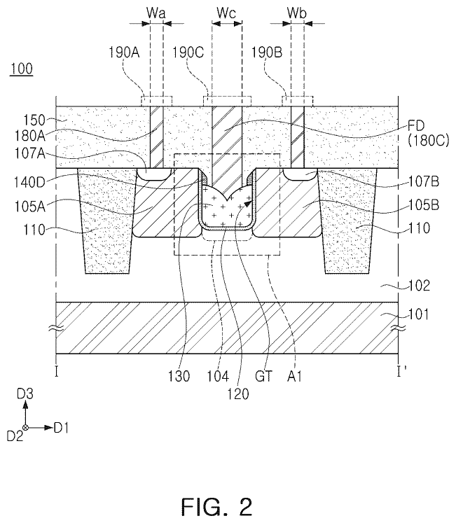

FIG. 1 is a plan view illustrating a high voltage semiconductor device according to some example embodiments, and FIG. 2 is a cross-sectional side view taken along line I-I′ of the high voltage semiconductor device illustrated in FIG. 1. In this case, FIG. 1 may be understood as a plan view of the high voltage semiconductor device with an interlayer insulating layer 150 excluded from FIG. 2.

Referring to FIGS. 1 and 2, a high voltage semiconductor device 100 according to some example embodiments may include a substrate 101, a well region 102 of a first conductivity-type within the substrate 101, first and second drift regions 105A and 105B of a second conductivity-type facing each other in a first direction D1 within the well region 102, and a buried gate electrode 130 between the first and second drift regions 105A and 105B.

The substrate 101 may include, for example, a semiconductor such as Si or Ge, or a compound semiconductor such as SiGe, SiC, GaAs, InAs, or InP. In another example, the substrate 101 may have a Silicon On Insulator (SOI) structure. However, example embodiments are not limited thereto. The substrate 101 may include first conductivity-type impurities, and thus may have the first conductivity-type. In some example embodiments, the first conductivity-type may be, for example, P-type, and the first conductivity-type impurities may be, for example, P-type impurities, such as aluminum (Al). In some example embodiments, the first conductivity-type may be, for example, N-type, and the first conductivity-type impurities may be, for example, N-type impurities, such as nitrogen (N) and/or phosphorus (P). However, example embodiments are not limited thereto.

A device isolation region 110 may be formed in a substrate 101 to define an active region for a high voltage semiconductor device 100. First and second drift regions 105A and 105B may be disposed on both sides of the active region defined by the device isolation region 110, respectively. As illustrated in FIG. 1, the device isolation region 110 may extend along a second direction D2 intersecting the first direction D1. The device isolation region 110 may include one or more of an insulating material of silicon oxide, silicon nitride, or silicon oxynitride filled in a trench formed in the well region 102. However, example embodiments are not limited thereto. For example, the device isolation region 110 is also called Shallow Trench Isolation (STI).

The well region 102 includes first conductivity-type impurities and thus may have a first conductivity-type. The well region 102 may also be referred to as a ‘high-voltage well region’. In some example embodiments, the first conductivity-type may be, for example, P-type, and the first conductivity-type impurities may be, for example, P-type impurities such as aluminum (Al). In some example embodiments, the first conductivity-type may be, for example, N-type, and the first conductivity-type impurities may be, for example, N-type impurities such as nitrogen (N) and/or phosphorus (P). In some example embodiments, the well region 102 may be formed by injection into the substrate 101 through a mask such as a photoresist pattern.

The first and second drift regions 105A and 105B include second conductivity-type impurities and thus may have a second conductivity-type. The first and second drift regions 105A and 105B may be formed to be exposed to the upper surface of the substrate 101. As illustrated in FIG. 1, the first and second drift regions 105A and 105B may extend along the second direction D2. In some example embodiments, the second conductivity-type may be, for example, an N-type, and the second conductivity-type impurities may be, for example, N-type impurities, such as nitrogen (N) and/or phosphorus (P). In some example embodiments, the second conductivity-type may be, for example, a P-type, and the second conductivity-type impurities may be, for example, P-type impurities, such as aluminum (Al). However, example embodiments are not limited thereto. In some example embodiments, the first and second drift regions 105A and 105B may be formed by injection into both sides of the well region 102 through a mask, such as a photoresist pattern.

The buried gate electrode 130 employed in some example embodiments may be formed in the gate trench GT between the first and second drift regions 105A and 105B. The gate trench GT may be formed by an etching process using a photolithography process. In some example embodiments, the gate trench GT may be formed after the first and second drift regions 105A and 105B are formed. The bottom of the gate trench GT may be provided by the well region 102, and two sidewalls of the gate trench GT may be provided by the first and second drift regions 105A and 105B. The sidewalls of the gate trench GT may be provided by the first and second drift regions 105A and 105B over almost the entire area.

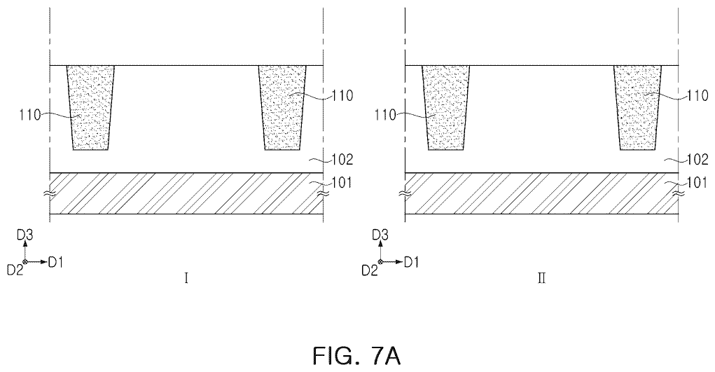

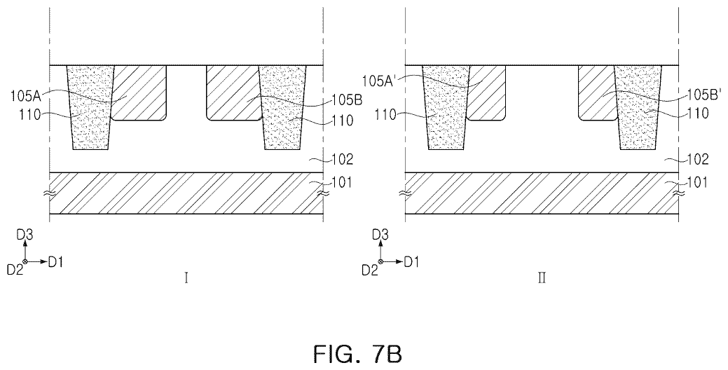

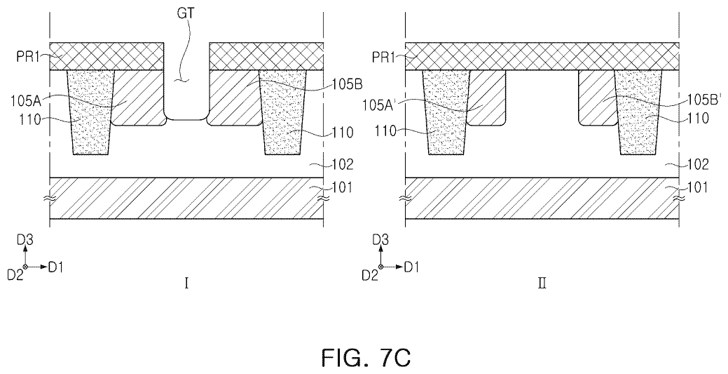

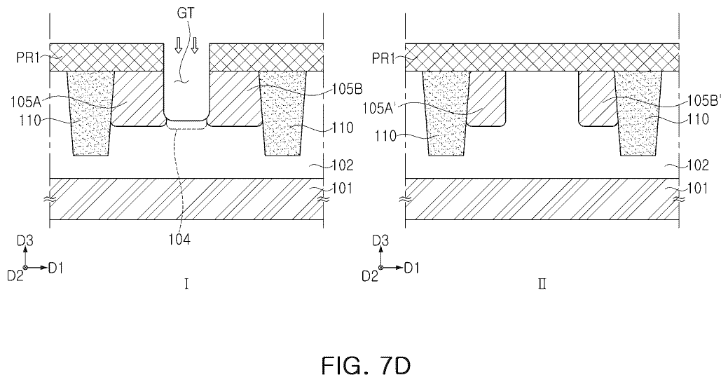

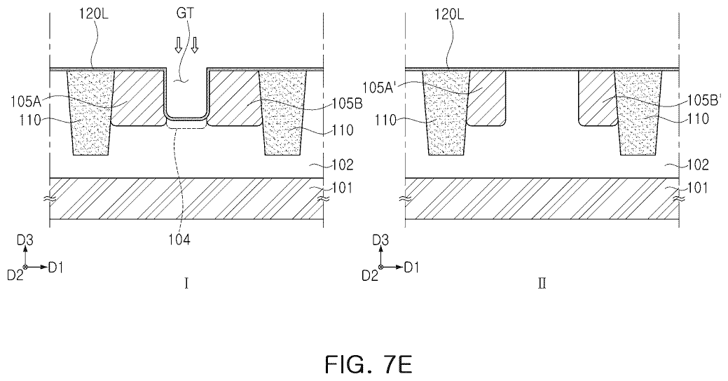

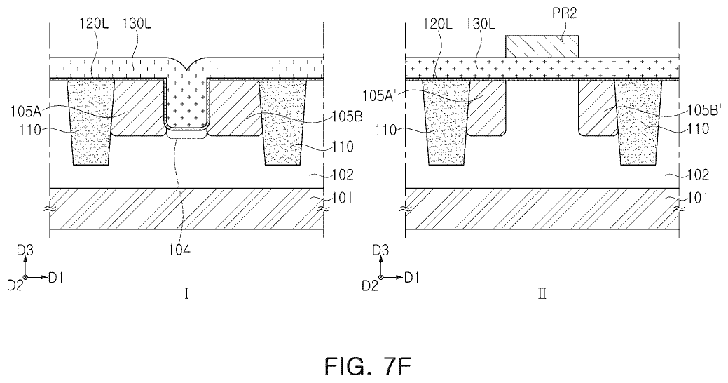

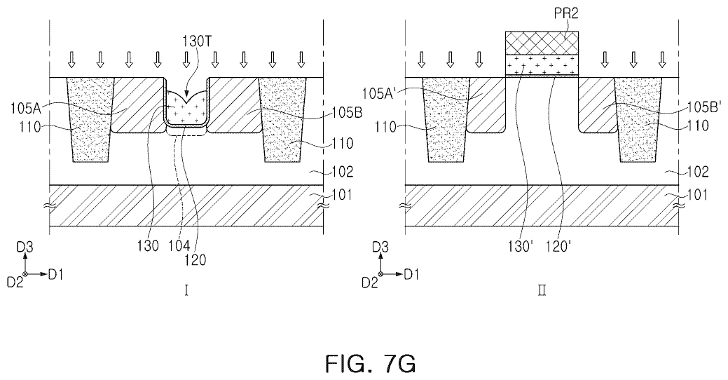

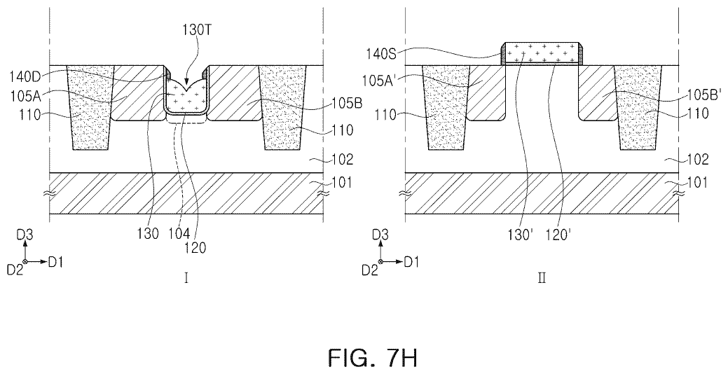

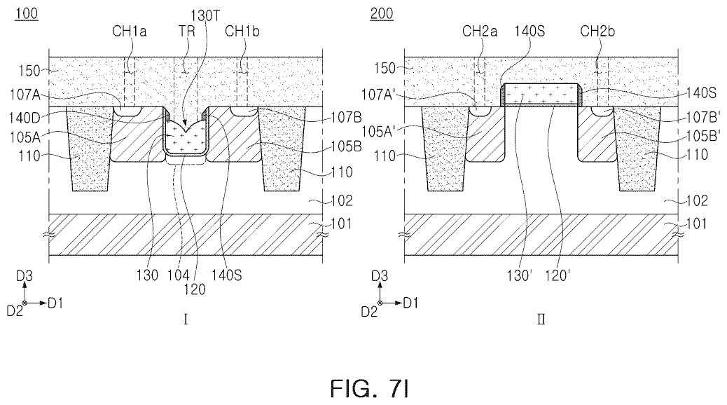

A high-concentration impurity region 104 for a channel region may be formed in a well region 102 exposed at the bottom of the gate trench GT. In some example embodiments, the high-concentration impurity region 104 may be obtained by an ion implantation process using a mask for forming the gate trench GT as it is without an additional mask (see FIG. 7D). The high-concentration impurity region 104 may be additionally implanted with impurities to control a threshold voltage. For example, the high-concentration impurity region 104 may have an impurity concentration higher than the impurity concentration of the well region 102 in a region defined as the bottom of the gate trench GT in the well region 102.

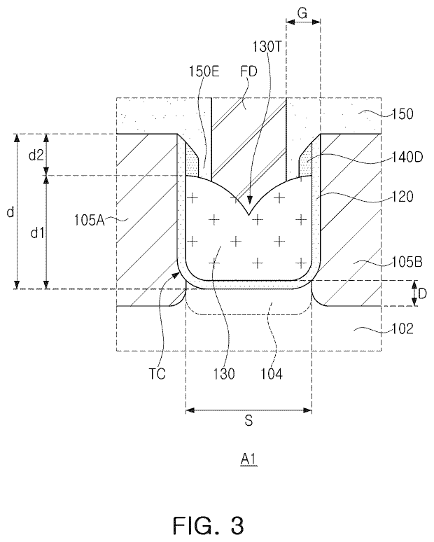

FIG. 3 is a partially enlarged view illustrating a portion A1 of the high voltage semiconductor device illustrated in FIG. 2.

Referring to FIG. 3 together with FIG. 2, the sidewall of the gate trench GT is illustrated as having a plane that is almost vertical with respect to the bottom of the gate trench GT (or the upper surface of the substrate 101), but example embodiments are not limited thereto, and in some example embodiments, the sidewall of the gate trench GT may be inclined with respect to the bottom of the gate trench GT.

In some example embodiments, the gate trench GT may be formed such that at least portions of both corners TC of the bottom thereof are covered by the first and second drift regions 105A and 105B. In some example embodiments, the bottom of the gate trench GT may be formed such that it is almost the same as or higher than the lower surfaces of the first and second drift regions 105A and 105B. Accordingly, the bottom of the gate electrode 130 in the gate trench GT may have a level equal to (or substantially equal to) or higher than the lower surfaces of the first and second drift regions 105A and 105B. In some example embodiments, the bottom of the gate electrode 130 may be higher than the lower surfaces of the first and second drift regions 105A and 105B by an amount indicated by “D”. For example, the depth d of the gate trench GT may be 0.3 μm to 0.6 μm, and the width S of the gate trench GT may be 0.4 μm to 0.8 μm.

The gate insulating film 120 may be conformally formed to cover the inner surface of the gate trench GT, for example, the bottom and two sidewalls. In some example embodiments, the gate insulating film 120 may extend to the upper end of the sidewall of the gate trench GT. The gate insulating film 120 may include, for example, silicon oxide, silicon oxynitride, a high-k dielectric, combinations thereof, or a laminated film thereof. However, example embodiments are not limited thereto. The high-k dielectric may include HfO₂, ZrO₂, Al₂O₃, Ta₂O₅, hafnium silicate, zirconium silicate, or combinations thereof. However, example embodiments are not limited thereto. When the gate insulating film 120 is silicon oxide, the silicon oxide may be formed by an oxidation process such as a thermal oxidation process, but example embodiments are not limited thereto, and the gate insulating film 120 may be formed by chemical vapor deposition (CVD), atomic layer deposition (ALD), physical vapor deposition (PVD), or combinations thereof. For example, the gate insulating film 120 may have a thickness of 100 Å to 500 Å.

The gate electrode 130 is buried in the lower region of the gate trench GT and may be disposed on the gate insulating film 120. For example, the gate electrode 130 may include polysilicon. The polysilicon may be doped with N-type or P-type impurities. In some example embodiments, the gate electrode 130 may include a metal such as tungsten.

The gate electrode 130 may be deposited by chemical vapor deposition (CVD) or physical vapor deposition (PVD). The gate electrode 130 employed in some example embodiments may be obtained by an etch-back process after the material of the gate electrode 130 is deposited without an additional mask (see FIG. 7G). As illustrated in FIGS. 2 and 3, the gate electrode 130 may have an upper surface 130T on which a concave-shaped valley is formed. This valley may extend in a second direction D2 in which the gate electrode 130 extends.

A level d1 of an upper end (a portion contacting the gate insulating film 120) of the gate electrode 130 may be located at a level of 50% or more of the entire depth d of the gate trench GT. In some example embodiments, the upper end level d1 of the gate electrode 130 may be located at a level of 70% or more of the entire depth d. In this way, the gate electrode in contact with the gate insulating film 120 may not be present in the upper region (the region indicated by “d2”) of the gate trench GT. In the off state, this gate electrode 130 does not extend to the upper end region of the first or second drift region 105A or 105B, and thus, it is advantageous for improving the breakdown voltage characteristics, but the GIDL characteristics may be degraded.

To improve the GIDL characteristics while maintaining the improved breakdown voltage characteristics, the high voltage semiconductor device 100 according to some example embodiments may include a field distribution structure FD disposed on the gate electrode 130 in the upper region of the gate trench GT. The field distribution structure FD may extend higher than the upper surfaces of the first and second drift regions 105A and 105B.

As illustrated in FIG. 3, both side surfaces of the field distribution structure FD may be spaced apart from the gate insulating film 120. The field distribution structure FD may be spaced apart from the sidewall of the gate trench GT by a gap G greater than the gap between the gate electrode 130 and the sidewall of the gate trench GT.

In detail, the gap between the gate electrode 130 and the first and second drift regions 105A and 105B is defined by the gate insulating film 120, while the gap G between the field distribution structure FD and the first and second drift regions 105A and 105B may be greater than the thickness of the gate insulating film 120. In some example embodiments, a portion 150E extending from the interlayer insulating layer 150 and a residual spacer material 140D may be positioned in the space between the field distribution structure FD and the gate insulating film 120. The residual spacer material 140D may be located on two sidewalls of the gate trench on the gate electrode 130. The residual spacer material 140D may be a spacer material remaining in the process of forming a gate spacer of a MOSFET device in another region of the substrate 101 (see FIG. 7H). For example, the residual spacer material 140D may include silicon nitride or silicon oxynitride. However, example embodiments are not limited thereto.

Referring to FIG. 1, the gate electrode 130 extends in the second direction D2 between the first and second drift regions 105A and 105B, and the field distribution structure FD may be spaced apart from the upper end regions of the first and second drift regions 105A and 105B by a certain interval and may extend along the second direction D2. In some example embodiments, the field distribution structure FD may have a bar type shape extending in the second direction D2 in a planar view.

In this way, the field distribution structure FD may maintain the improved breakdown voltage characteristic by the low gate electrode 130 by being separated from the upper end regions of the first and second drift regions 105A and 105B, and may disperse the electric field concentrated on the upper end of the gate electrode 130 by extending in the second direction D2 from the upper end regions of the first and second drift regions 105A and 105B, thereby further improving GIDL characteristic.

Referring to FIGS. 1 and 2, the source/drain regions 107A and 107B may be disposed in the first and second drift regions 105A and 105B, respectively. The source/drain regions 107A and 107B may have an impurity concentration higher than the impurity concentration of the first and second drift regions 105A and 105B. The plurality of source/drain regions 107A and 107B have the same second conductivity-type as the first and second drift regions 105A and 105B. The plurality of source/drain regions 107A and 107B may be arranged in the second direction D2 in the first and second drift regions 105A and 105B. The plurality of source/drain regions 107A and 107B may be formed by implanting second conductivity-type impurities into the first and second drift regions 105A and 105B through a mask such as a photoresist pattern. In some example embodiments, the plurality of source/drain regions 107A and 107B may be connected to each other in the first and second drift regions 105A and 105B and configured in a line type.

A plurality of source/drain regions 107A and 107B are formed from surfaces of the first and second drift regions 105A and 105B and may have a thickness thinner than the thicknesses of the first and second drift regions 105A and 105B. The source/drain regions 107A and 107B may be spaced further from the gate trench GT than the first and second drift regions 105A and 105B. The arrangement of the source/drain regions 107A and 107B as above may improve breakdown voltage characteristics.

Referring to FIG. 2, a high voltage semiconductor device 100 according to some example embodiments may further include an interlayer insulating layer 150 covering first and second drift regions 105A and 105B and the gate electrode 130, on a substrate 101, and a plurality of first and second contact plugs 180A and 180B penetrating the interlayer insulating layer 150 and electrically connected to the first and second drift regions 105A and 105B, respectively. For example, the plurality of first and second contact plugs 180A and 180B may include at least one of nickel (Ni), aluminum (Al), titanium (Ti), silver (Ag), vanadium (V), tungsten (W), cobalt (Co), molybdenum (Mo), copper (Cu), and ruthenium (Ru). However, example embodiments are not limited thereto. In some example embodiments, the source/drain regions contacting the plurality of first and second contact plugs 180A and 180B may include a metal-semiconductor compound layer (not illustrated) to lower the contact resistance. For example, the metal-semiconductor compound layer may include at least one of TiSi, CoSi, MoSi, LaSi, NiSi, TaSi, or WSi. However, example embodiments are not limited thereto.

Referring to FIG. 1, the plurality of first and second contact plugs 180A and 180B may be arranged along the second direction D2. The plurality of first and second contact plugs 180A and 180B may be connected to the source/drain regions 107A and 107B, respectively, and may be electrically connected to the first and second drift regions 105A and 105B through the source/drain regions 107A and 107B.

In some example embodiments, the field distribution structure FD may include a different conductive material from the gate electrode 130. For example, the field distribution structure FD may include at least one of nickel (Ni), aluminum (Al), titanium (Ti), silver (Ag), vanadium (V), tungsten (W), cobalt (Co), molybdenum (Mo), copper (Cu), and ruthenium (Ru). However, example embodiments are not limited thereto. The field distribution structure FD may include the same material as the first and second contact plugs 180A and 180B. As described above, the field distribution structure FD is a bar type shape extending in the second direction D2 in a planar view, but similar to the first and second contact plugs 180A and 180B, it may be used as a third contact plug 180C connected to the gate electrode 130. First to third interconnection patterns 190A, 190B and 190C are disposed on the interlayer insulating layer 150, and the first to third interconnection patterns 190A, 190B and 190C may be connected to the first to third contact plugs 180A, 180B and 180C, respectively.

Referring to FIG. 2, the field distribution structure FD is formed in consideration of the gap between the first and second drift regions 105A and 105B within the gate trench GT, and therefore may have a width Wc different from the widths Wa and Wb of the first and second contact plugs 180A and 180B, respectively. In some example embodiments, the width Wc of the field distribution structure FD may be larger than the widths Wa and Wb of the first and second contact plugs 180A and 180B, respectively. The field distribution structure FD may have an upper surface at the same level as the upper surfaces of the first and second contact plugs 180A and 180B. After forming holes for the first and second contact plugs 180A and 180B and a trench for the field distribution structure FD in the interlayer insulating layer 150, a conductive material may be filled in the holes and the trench, and then chemical mechanical polishing (CMP) may be applied until the upper surface of the interlayer insulating layer 150 is exposed to remove the conductive material remaining on the interlayer insulating layer 150.

According to some example embodiments, the breakdown voltage characteristics may be improved by lowering the gate electrode 130 in the gate trench. In addition, by separating the field distribution structure FD that is on the gate electrode 130 from the upper end regions of the first and second drift regions 105A and 105B, the improved breakdown voltage characteristics may be maintained while dispersing the electric field concentrated on the upper end of the gate electrode 130, and thus, the GIDL characteristics may be improved.

To confirm the effect according to some example embodiments, the electrical characteristics of high voltage semiconductor devices (Comparative Examples 1, 2, and the example embodiments) having various gate structures were compared.

It may be understood that the high voltage semiconductor devices according to Comparative Examples 1, 2, and the example embodiments have the same specifications except that they differ only in the shape of the gate electrode and the presence or absence of the field distribution structure.

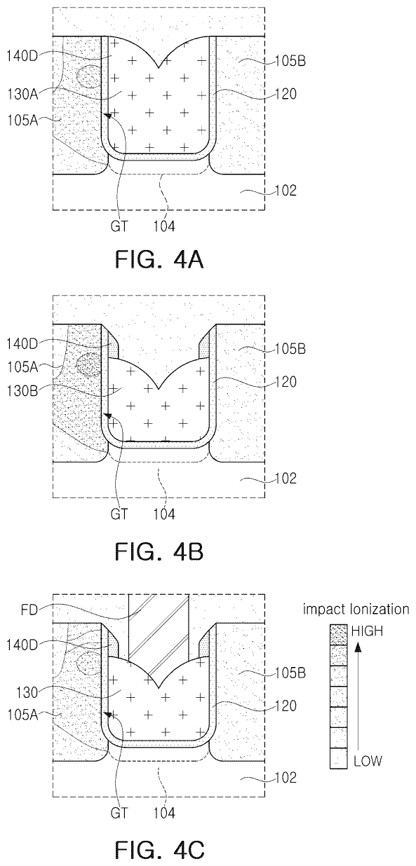

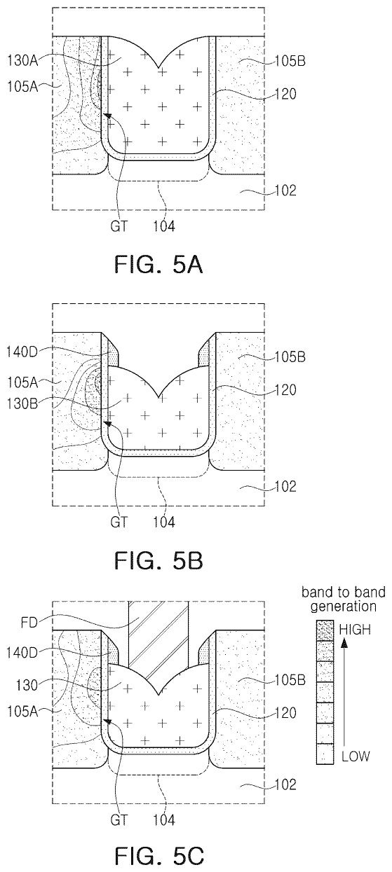

First, in the high voltage semiconductor device (Comparative Example 1) of FIGS. 4A and 5A, the gate electrode 130A is provided to fill almost the entire area of the gate trench GT, and in the high voltage semiconductor device (Comparative Example 2) of FIGS. 4B and 5B, the gate electrode 130B may be provided to fill the lower region (about 80% of the entire depth) of the gate trench GT. In Comparative Examples 1 and 2, third contact plugs (not illustrated) connected to the gate electrodes 130A and 130B may be connected to any points of the gate electrodes 130A and 130B extending in one direction from a planar viewpoint.

In contrast, the high voltage semiconductor device (example embodiments) of FIGS. 4C and 5C is similar to Comparative Example 2 in that the gate electrode 130 fills the lower region (approximately 80% of the entire depth) of the gate trench GT, a field distribution structure FD is provided on the gate electrode 130, and the field distribution structure FD has a bar type shape that extends along the extension direction of the gate electrode 130.

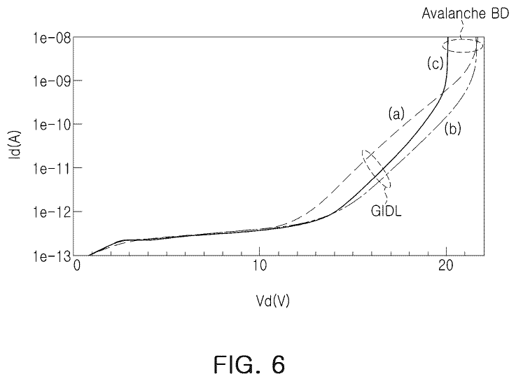

FIGS. 4A to 4C are schematic diagrams illustrating impact ionization in high voltage semiconductor devices having various gate structures (Comparative Examples 1, 2, and the example embodiments), and FIGS. 5A to 5C are schematic diagrams illustrating band-to-band generation distribution in high voltage semiconductor devices having various gate structures (Comparative Examples 1, 2, and the example embodiments). In addition, FIG. 6 illustrates I-V curves of high voltage semiconductor devices according to Comparative Examples 1 and 2 and the example embodiments, and in detail, the results measured in the drain region in the gate-off state.

Referring to FIGS. 4A and 4B and FIG. 6, by lowering the gate electrode within the gate trench GT (130A→130B), the distance between the gate electrode and the drain region increases, and as a result, avalanche breakdown at the surface of the first drift region 105A may be delayed or improved. In this way, Comparative Example 2 may have improved breakdown voltage characteristics compared to Comparative Example 1.

On the other hand, referring to FIGS. 5A and 5B and FIG. 6, Comparative Example 2 may have worse GIDL characteristics compared to Comparative Example 1 because band-to-band carrier generation (B2B) increases in the sidewall of the gate trench adjacent to the upper end of the gate electrode, for example, the first drift region 105A.

Referring to FIGS. 4C and 6, in some example embodiments, improved breakdown voltage characteristics may be maintained similarly to the gate electrode 130B of Comparative Example 2 by disposing a field distribution structure FD on the gate electrode while separating the field distribution structure FD from the upper end regions of the first and second drift regions 105A and 105B. In addition, referring to FIGS. 5C and 6, in some example embodiments, the GIDL characteristics may further be improved by dispersing the electric field concentrated on the upper end of the gate electrode 130 by the field distribution structure FD extending along the extension direction of the gate electrode 130 between the first and second drift regions 105A and 105B.

In this way, the high voltage semiconductor device 100 according to some example embodiments may significantly improve the electrical characteristics in the off state by forming the gate electrode 130 in the lower region of the gate trench GT and disposing the field distribution structure FD extending along the gate electrode on the gate electrode 130.

FIGS. 7A to 7I are cross-sectional views for respective main processes, illustrating a method of manufacturing a high voltage semiconductor device according to some example embodiments. The process according to some example embodiments may be understood as a process of simultaneously forming a high voltage semiconductor device 100 of FIGS. 1 to 3 and another planar MOSFET element in the first region I and the second region II of one substrate 101, respectively.

Referring to FIG. 7A, a well region 102 of the first conductivity-type may be formed on the first region I and the second region II of the substrate 101, and a device isolation region 110 defining an active region may be formed.

The substrate 101 introduced in some example embodiments may include, for example, a semiconductor such as Si or Ge, or a compound semiconductor such as SiGe, SiC, GaAs, InAs, or InP. In another example, the substrate 101 may have a silicon on insulator (SOI) structure. However, example embodiments are not limited thereto. The substrate 101 may be a first conductivity-type substrate including first conductivity-type (for example, P-type) impurities. Next, by injecting a first conductivity-type impurity into the first region I and the second region II of the substrate 101 through a mask such as a photoresist pattern, a first conductivity-type well region 102 may be formed. In the second region II, when a low-voltage MOSFET or another conductivity-type MOSFET is formed, a well region with a different impurity concentration or a well region with a different conductivity-type impurity concentration may be formed in the second region II using an additional mask.

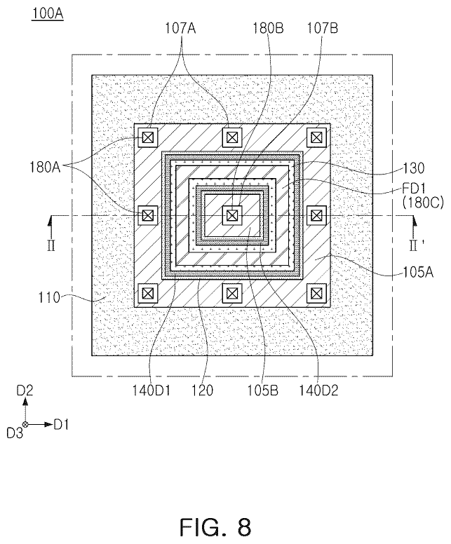

Device isolation regions 110 may be formed in each of the first region I and the second region II of the substrate 101, to define an active region for forming a device (for example, a MOSFET). The device isolation regions 110 may be extended along a second direction D2 intersecting the first direction D1. In this way, an active region extending in the second direction D2 may be provided in each of the first region I and the second region II of the substrate 101. In some example embodiments, the device isolation region 110 may be formed differently from a planar viewpoint to form a semiconductor device having a different layout (for example, see FIG. 8).

Next, referring to FIG. 7B, first and second drift regions 105A and 105B, and 105A′ and 105B′ may be formed in the first region I and the second region II of the substrate 101, respectively.

In this process, the first and second drift regions 105A and 105B, and 105A′ and 105B′ may be formed by injecting second conductivity-type impurities into both sides of the active region (for example, well region 102) of each of the first region I and the second region II of the substrate 101 using a mask such as a photoresist pattern. In the first region I of the substrate 101, as illustrated in FIG. 1, the first and second drift regions 105A and 105B may extend along the second direction D2. Similarly, in the second region II of the substrate 101, the first and second drift regions 105A′ and 105B′ may extend along the second direction D2.

The present inventive concepts are not limited thereto, and in some example embodiments, as described above, the first and second drift regions 105A and 105B, and 105A′ and 105B′ may have different layouts according to the pattern of the active region defined by the device isolation region 110.

Next, referring to FIG. 7C, a gate trench GT may be formed in the first region I of the substrate 101 using a first photoresist pattern PR1.

The first photoresist pattern PR1 has an opening defining a gate trench GT in the first region I of the substrate 101 and may be formed to entirely cover the second region II of the substrate 101. The gate trench GT may be formed by an etching process using the first photoresist pattern PR1.

The gate trench GT may be formed after the first and second drift regions 105A and 105B are formed. In some example embodiments, the gate trench GT may extend in the second direction D2. By controlling the position and width of the gate trench GT, the first and second drift regions 105A and 105B may be formed so that they are open on two sidewalls of the gate trench GT.

In addition, the gate trench GT may be formed so that a well region 102 is open on the bottom thereof. In some example embodiments, the bottom of the gate trench GT may be substantially the same as or higher than the lower surfaces of the first and second drift regions 105A and 105B. For example, the lower corner of the gate trench GT may be at least partially covered by the first and second drift regions 105A and 105B.

In some example embodiments, the sidewall of the gate trench GT is exemplified as having a surface substantially vertical with respect to the upper surface of the substrate 101, but example embodiments are not limited thereto, and in some example embodiments, the sidewall of the gate trench GT may have a slightly inclined surface.

Next, referring to FIG. 7D, an ion implantation process may be performed on the bottom of the gate trench GT using the first photoresist pattern PR1.

This ion implantation process may be introduced as a process for controlling the threshold voltage of the channel region 104. For example, a first conductivity-type impurity may be additionally injected in the present process. The first photoresist pattern PR1 used to form the gate trench GT in the present ion implantation process may be used as is. A channel region 104 with a threshold voltage adjusted may be formed at the bottom of the gate trench GT. In some example embodiments, even if the sidewall of the gate trench GT is somewhat inclined, since the impurity to be ion-implanted is relatively small, it may not have a significant effect in the region of the first and second drift regions 105A and 105B having a relatively high concentration, adjacent to the sidewall.

Next, referring to FIG. 7E, after removing the first photoresist pattern PR1, a gate insulating film 120L may be formed in the first region I and the second region II of the substrate 101.

In the first region I of the substrate 101, the gate insulating film 120L may be conformally formed to cover the inner surface of the gate trench GT, for example, the bottom and two sidewalls. For example, the gate insulating film 120L may include silicon oxide, silicon oxynitride, a high-k dielectric, combinations thereof, or a laminated film thereof. However, example embodiments are not limited thereto. The high-k dielectric may include HfO₂, ZrO₂, Al₂O₃, Ta₂O₅, hafnium silicate, zirconium silicate, or combinations thereof. However, example embodiments are not limited thereto.

In some example embodiments, the same gate insulating film 120L is formed in both the first region I and the second region II of the substrate 101, but a gate insulating film different from the gate insulating film of the first region I may be formed in the second region II. For example, when forming a low-voltage MOSFET in the second region II of the substrate 101, a gate insulating film of a different material and/or a different number of layers may be formed in the second region II using an additional mask.

Next, referring to FIG. 7F, a conductive material layer 130L for a gate electrode may be formed on the first region I and the second region II of the substrate 101.

The conductive material layer 130L may fill a gate trench GT in the first region I of the substrate 101. The conductive material layer 130L may include polysilicon. The polysilicon may be doped with an N-type or P-type impurity. In some example embodiments, the conductive material layer 130L may include a metal such as tungsten. The conductive material layer 130L may be deposited by chemical vapor deposition (CVD) or physical vapor deposition (PVD).

Next, a second photoresist pattern PR2 may be formed on a portion of the conductive material layer 130L located in the second region II of the substrate 101. The second photoresist pattern PR2 may define a portion corresponding to the gate electrode in the conductive material layer 130L.

Next, referring to FIG. 7G, an etch-back process may be performed on the conductive material layer 130L in the first region I and the second region II of the substrate 101 to form gate electrodes 130 and 130′ and gate insulating films 120 and 120'.

In this process, in the first region I of the substrate 101, the gate electrode 130 may remain in the lower region of the gate trench GT through an etch-back process on the entire surface without an additional mask, and in the second region II, a gate electrode 130′ defined by the second photoresist pattern PR2 may be formed. During this etch-back process, or after performing the etch-back process, by removing the exposed gate insulating film portions through a separate etching process, gate insulating films 120 and 120′ may be formed in the first region I and the second region II of the substrate 101, respectively.

Next, referring to FIGS. 7H and 7I, a gate spacer 140S may be formed on the sidewall of the gate electrode 130′ in the second region II of the substrate 101.

The process of forming the gate spacer 140S may be performed by forming a spacer material layer over the first region I and the second region II of the substrate 101 and applying anisotropic etching to remove portions of the spacer material layer from surfaces parallel to the upper surface of the substrate 101.

In the formation process of the gate spacer 140S, a residual spacer material 140D may be formed on the inner sidewall portion of the gate trench GT located on the gate electrode 130 in the first region I of the substrate 101.

Additionally, source/drain regions 107A and 107B, and 107A′ and 107B′ may be formed in the first and second drift regions 105A and 105B, and 105A′ and 105B′ in the first region I and the second region II of the substrate 101, respectively. The source/drain regions 107A, 107B, 107A′ and 107B′ may have an impurity concentration higher than the impurity concentrations of the first and second drift regions 105A, 105B, 105A′ and 105B'.

Next, referring to FIG. 7I, an interlayer insulating layer 150 may be formed on the first region I and the second region II of the substrate 101, and contact holes CH1a, CH1b, CH2a and CH2b connected to the source/drain regions 107A, 107B, 107A and 107B and a trench TR for a field distribution structure FD may be formed in the interlayer insulating layer 150. In a planar view, unlike the contact holes CH1a, CH1b, CH2a and CH2b, the trench TR may have a shape that extends in the second direction D2 along the gate electrode 130.

In the subsequent process, the contact holes CH1a, CH1b, CH2a and CH2b and the trench TR are filled with a conductive material, and then chemical mechanical polishing (CMP) is applied until the upper surface of the interlayer insulating layer 150 is exposed, to remove the conductive material remaining on the interlayer insulating layer 150. As a result, a high voltage semiconductor device 100 (or a high voltage MOSFET) as illustrated in FIGS. 1 to 3 is provided in the first region I of the substrate 101, and a MOSFET 200 of a planar structure may be formed in the second region II of the substrate 101.

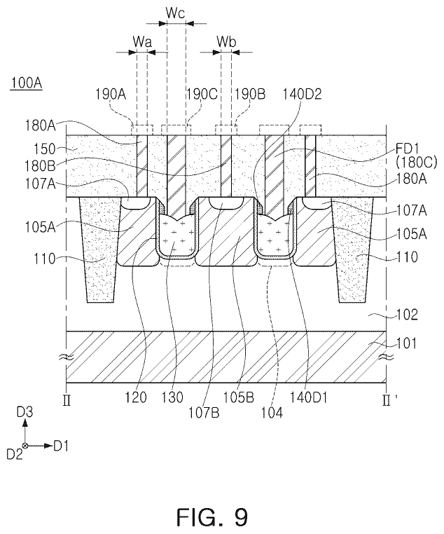

FIGS. 8 and 9 are a plan view and a side cross-sectional view illustrating a high voltage semiconductor device according to some example embodiments, respectively.

Referring to FIGS. 8 and 9, a high voltage semiconductor device 100A according to some example embodiments may be understood as being similar to the high voltage semiconductor device 100 illustrated in FIGS. 1 to 3, except that it has a ring-type structure in a plan view and has a ring-type field distribution structure FD1 corresponding to the gate electrode 130. In addition, unless otherwise specifically described, the components of some example embodiments may be understood by referring to the description of the same or similar components of the high voltage semiconductor device 100 illustrated in FIGS. 1 to 3.

Unlike the high voltage semiconductor device 100 according to the previous example embodiments, the high voltage semiconductor device 100A according to some example embodiments has a quadrangular ring-type structure in a plan view.

Referring to FIG. 8, the device isolation region 110 is formed in a quadrangular ring type shape, and a quadrangular active region may be defined within the device isolation region 110. A first drift region 105A may be formed with a constant width along the inner side of the device isolation region 110. A second drift region 105B may be formed in a quadrangular shape at the center of the quadrangular active region.

Referring to FIG. 9 together with FIG. 8, a gate trench GT is formed between the first drift region 105A and the second drift region 105B, for example, on the inner side of the first drift region 105A and the outer side of the second drift region 105B, and this gate trench GT may have a quadrangular ring type shape in a planar view. A gate insulating film 120 may be conformally formed to cover the inner surface of the gate trench GT, for example, the bottom and two sidewalls.

The gate electrode 130 is disposed on the gate insulating film 120 to be buried in the lower region of the gate trench GT and may have a quadrangular ring type shape in a planar view. The upper end level of the gate electrode 130 may be located at a level of 50% or more (for example, 70% or more) of the entire depth of the gate trench GT. A gate electrode in contact with the gate insulating film 120 may not be present in the upper region of the gate trench GT.

The high voltage semiconductor device 100A according to some example embodiments may include a field distribution structure FD1 disposed on the gate electrode 130 in the upper region of the gate trench GT. The field distribution structure FD1 may extend higher than the upper surfaces of the first and second drift regions 105A and 105B.

In addition, both side surfaces of the field distribution structure FD1 may be spaced apart from the sidewall of the gate trench GT by a gap greater than the gap between the gate electrode 130 and the sidewall of the gate trench GT. This field distribution structure FD1 may improve the GIDL characteristics while maintaining the improved breakdown voltage characteristics by lowering the gate electrode 130.

In some example embodiments, a portion extending from the interlayer insulating layer 150 and first and second residual spacer materials 140D may be positioned in the space between the field distribution structure FD1 and the gate insulating film 120. The first residual spacer material 140D1 may be positioned adjacent to the first drift region 105A, and the second residual spacer material 140D2 may be positioned adjacent to the second drift region 105B.

Referring to FIG. 9, the plurality of drain regions 107A are illustrated as being arranged in the first drift region 105A and the source region 107B is illustrated as being arranged in the center of the second drift region 105A, but the present inventive concepts are not limited thereto. In some example embodiments, the source region 107B may also be arranged in multiples. The plurality of first contact plugs 180A and second contact plugs 180B may be connected to the plurality of drain regions 107A and the source region 107B, respectively, and may be electrically connected to the first and second drift regions 105A and 105B.

The field distribution structure FD1 employed in some example embodiments may include a different conductive material from the gate electrode 130. For example, the field distribution structure FD1 may include the same material as the first and second contact plugs 180A and 180B. As described above, the field distribution structure FD1 may be extended to a ring type shape that is a quadrangular shape according to the gate electrode 130 in a planar view.

In some example embodiments, the layout of the ring type shape is described as a quadrangular shape as an example, but the present inventive concepts are not limited thereto, and in some example embodiments, the layout of the ring type shape may have a circular shape or another polygonal shape, and in some other embodiments, even if it has a quadrangular shape, a shape with rounded corners may be provided.

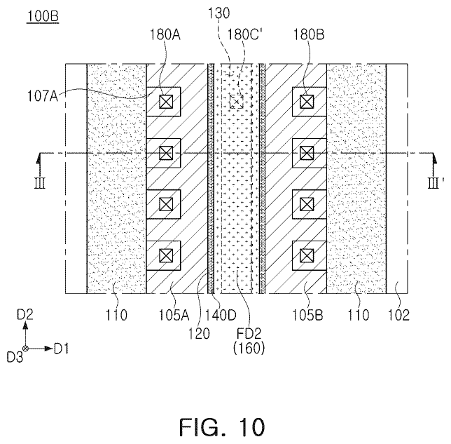

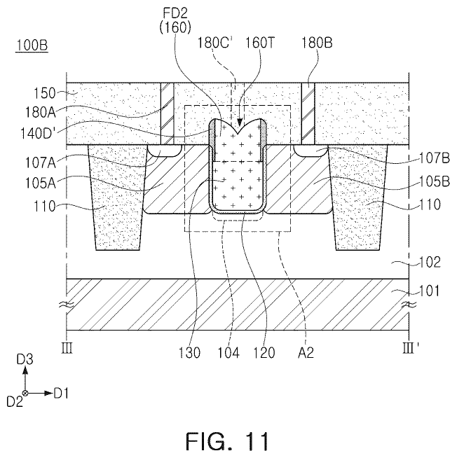

FIG. 10 and FIG. 11 are a plan view and a side cross-sectional view, respectively, illustrating a high voltage semiconductor device according to some example embodiments.

Referring to FIGS. 10 and 11, a high voltage semiconductor device 100B according to some example embodiments may be understood as being similar to the high voltage semiconductor device 100 illustrated in FIGS. 1 to 3, except that the field distribution structure FD2 includes the same material as the gate electrode 130 and is integrated with the gate electrode 130, a valley is formed on the upper surface of the field distribution structure FD2, and a residual spacer material 140D is disposed on both side surfaces of the field distribution structure FD2. In addition, unless otherwise specifically stated, the components of some example embodiments may be understood by referring to the description of the same or similar components of the high voltage semiconductor device 100 illustrated in FIGS. 1 to 3.

The field distribution structure FD2 employed in some example embodiments includes the same material as the gate electrode 130 and may include an electrode structure 160 integrated with the gate electrode 130. The field distribution structure FD2 may be extended along the extended direction (for example, D2 of the gate electrode 130). In some example embodiments, the field distribution structure FD may have an upper surface 160T in which a concave-shaped valley is formed. This valley may be extended in the second direction D2 in which the field distribution structure FD2 is extended.

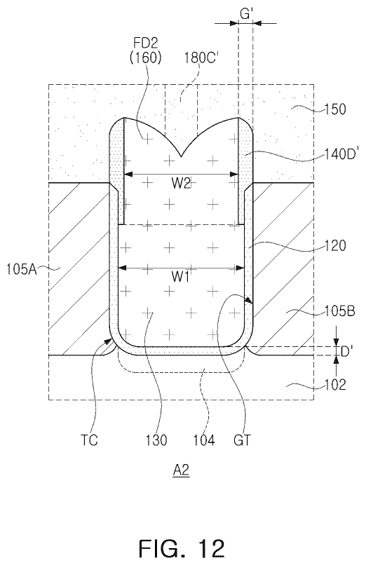

FIG. 12 is a partially enlarged view illustrating a portion A2 of the high voltage semiconductor device illustrated in FIG. 11.

Referring to FIG. 12 together with FIG. 11, the field distribution structure FD2 is an electrode structure 160 integrated with the gate electrode 130, but the gate electrode 130 is in contact with the gate insulating film 120, while both side surfaces of the field distribution structure FD2 may be spaced apart from the sidewall of the gate trench GT by a constant gap G'. In this way, the width W2 of the field distribution structure FD2 in the first direction D1 may be smaller than the width W1 of the gate electrode 130 in the first direction D1.

In some example embodiments, the field distribution structure FD2 may include residual spacer material 140D′ respectively disposed on the side surfaces facing the first and second drift regions 105A and 105B. The residual spacer material 140D′ may also extend into the space between the field distribution structure FD2 and the gate insulating film 120.

As illustrated in FIG. 12, the gate trench GT may be formed such that at least portions of both corners TC of the bottom thereof are covered by the first and second drift regions 105A and 105B. In some example embodiments, the bottom of the gate trench GT may be formed to be substantially the same as or lower than the lower surfaces of the first and second drift regions 105A and 105B. The bottom of the gate electrode 130 may be higher than the lower surfaces of the first and second drift regions 105A and 105B by an amount indicated by “D'.”

The field distribution structure FD2 employed in some example embodiments is also different in that it is provided in an integrated form with the gate electrode, but both side surfaces of the field distribution structure FD2 may be spaced apart from the sidewall of the gate trench GT by a gap greater than the gap between the gate electrode 130 and the sidewall of the gate trench GT. This field distribution structure FD1 may improve the GIDL characteristics while maintaining the improved breakdown voltage characteristics by lowering the gate electrode 130.

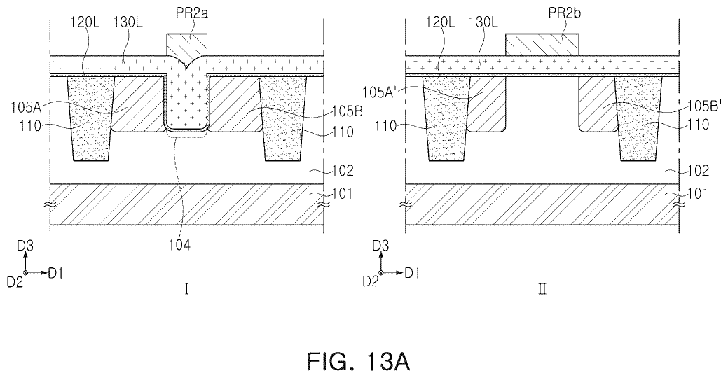

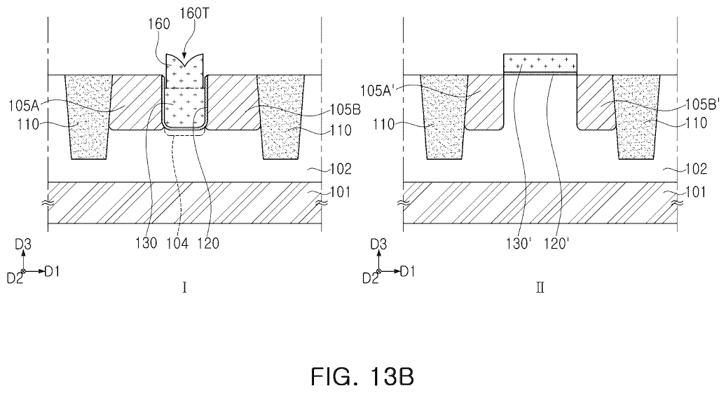

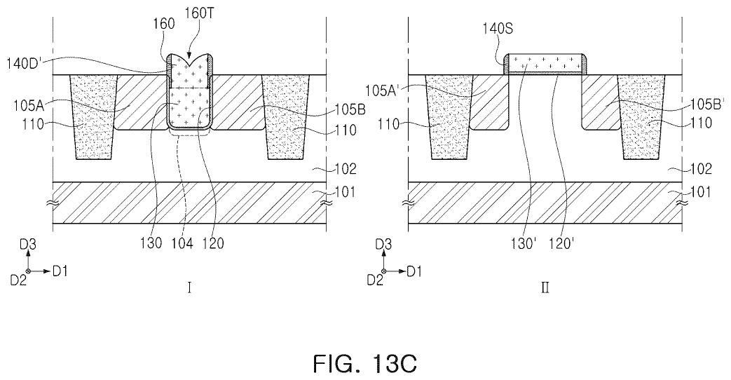

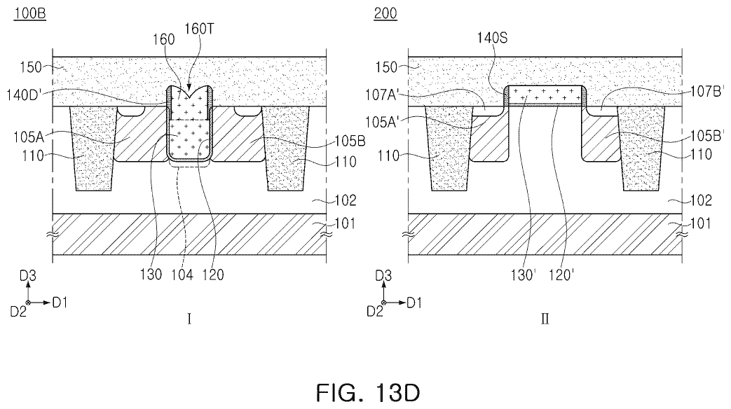

FIGS. 13A to 13D are cross-sectional views of major processes, illustrating a method of manufacturing a high voltage semiconductor device according to some example embodiments. The process according to some example embodiments may be understood as a process of simultaneously forming a high voltage semiconductor device 100B of FIGS. 10 to 12 and another planar MOSFET element in the first region I and the second region II of one substrate 101, respectively.

The process of FIG. 13A may be understood as a process performed following the process of FIG. 7E in the manufacturing process according to the previous example embodiments.

Referring to FIG. 13A, a conductive material layer 130L for a gate electrode is formed on the first region I and the second region II of the substrate 101, and then second photoresist patterns PR2a and PR2b may be formed in some regions of the conductive material layer 130L in the first region I and the second region II of the substrate 101.

First, the conductive material layer 130L may fill the gate trench GT in the first region I of the substrate 101. The conductive material layer 130L may include polysilicon. The polysilicon may be doped with N-type or P-type impurities. In some example embodiments, the conductive material layer 130L may also include a metal such as tungsten. The conductive material layer 130L may be deposited by chemical vapor deposition (CVD) or physical vapor deposition (PVD). Then, the second photoresist patterns PR2a and PR2b may define portions corresponding to the gate electrode in the conductive material layer 130L.

In some example embodiments, the second photoresist pattern PR2a disposed in the first region I of the substrate 101 may be configured to not only define the gate electrode 130, but also form a field distribution structure FD2. The second photoresist pattern PR2a may be formed so that the field distribution structure FD2 has a width W2 smaller than the width of the gate trench GT, as described in FIG. 12.

Next, referring to FIG. 13B, the second photoresist patterns PR2a and PR2b may be used to etch the conductive material layer 130L in the first region I and the second region II of the substrate 101, thereby forming gate electrodes 130 and 130′ and gate insulating films 120 and 120′.

In this process, the gate electrodes 130 and 130′ and the gate insulating films 120 and 120′ may be formed in the first region I and the second region II of the substrate 101, respectively. In detail, in the first region I of the substrate 101, by selectively etching the conductive material layer 130L using the second photoresist patterns PR2a, the field distribution structure FD2 may be formed so that both side surfaces thereof are spaced apart from the sidewalls of the gate trench GT. On the other hand, by appropriately controlling the etching process conditions (for example, time and/or process gas flow), the field distribution structure FD2 having a relatively small width (‘W2’ in FIG. 12) is formed from the conductive material layer 130L in the first region I, but a portion of the conductive material layer 130L located below the field distribution structure FD2 may remain as it is. The remaining portion of the conductive material layer 130L may be provided as a gate electrode 130 having a width (‘W1’ in FIG. 12) defined by the width of the gate trench GT. In the second region II of the substrate 101, a gate electrode 130′ may be formed as described in FIG. 7G using second photoresist patterns PR2b.

Additionally, during the main etching process or after performing the etching process, by removing exposed gate insulating film portions through an additional etching process, gate insulating films 120 and 120′ may be formed in the first region I and the second region II of the substrate 101, respectively.

Next, referring to FIG. 13C and FIG. 13D, a gate spacer 140S may be formed on a side wall of a gate electrode 130′ in a second region II of a substrate 101.

The process of forming the gate spacer 140S may be performed by forming a spacer material layer over the first region I and the second region II of the substrate 101, and applying anisotropic etching to remove portions of the spacer material layer from surfaces parallel to the upper surface of the substrate 101.

In the process of forming the gate spacer 140S, a residual spacer material 140D′ may be formed on both side surfaces of a field distribution structure FD2 protruding on the gate electrode 130 in the first region I of the substrate 101.

Additionally, source/drain regions 107A and 107B, and 107A′ and 107B′ may be formed in the first and second drift regions 105A and 105B, and 105A′ and 105B′ in the first region I and the second region II of the substrate 101, respectively. The source/drain regions 107A, 107B, 107A′ and 107B′ may have an impurity concentration higher than that of the first and second drift regions 105A, 105B, 105A′ and 105B′.

Next, referring to FIG. 13D, an interlayer insulating layer 150 is formed on the first region I and the second region II of the substrate 101, and as described in the process of FIG. 7I among the processes of the previous example embodiments, first contact holes connected to the source/drain regions 107A, 107B and 107A, 107B and a second contact hole for a field distribution structure FD2 may be formed in the interlayer insulating layer 150. In some example embodiments, the second contact hole may be connected to a part of the field distribution structure FD2 similarly to the first contact holes in a planar view, and a driving voltage may be applied to the gate electrode 130 through the field distribution structure FD2.

In a subsequent process, a conductive material may be filled in the first and second contact holes, and then the conductive material remaining on the interlayer insulating layer 150 may be removed by applying chemical mechanical polishing (CMP) until the upper surface of the interlayer insulating layer 150 is exposed. As a result, a high voltage semiconductor device 100B (or a high voltage MOSFET) as illustrated in FIGS. 10 to 12 may be provided in the first region I of the substrate 101, and a planar-structured MOSFET 200 may be formed in the second region II of the substrate 101.

As set forth above, according to some example embodiments described above, by introducing a buried gate electrode and a field distribution structure within a trench in a high voltage semiconductor device, not only breakdown voltage characteristics may be improved, but also Gate Induced Drain Leakage (GIDL) characteristics may be improved.

While example embodiments have been illustrated and described above, it will be apparent to those skilled in the art that modifications and variations could be made without departing from the scope of the present inventive concepts as defined by the appended claims.

What is claimed is:

1. A high voltage semiconductor device comprising:
a substrate;
a well region of a first conductivity-type within the substrate;
a first drift region and second drift region of a second conductivity-type in the well region;
a gate trench including
a bottom between the first drift region and the second drift region, the bottom partially defining the well region, and
a first sidewall and a second sidewall facing each other, the first sidewall and the second sidewall partially defining the first drift region and the second drift region, respectively;
a gate insulating film covering the bottom, the first sidewall, and the second sidewall of the gate trench;
a gate electrode buried in a lower region of the gate trench; and
a field distribution structure on the gate electrode in an upper region of the gate trench, and extending higher than an upper surface of the first drift region and an upper surface of the second drift region.

2. The high voltage semiconductor device of claim 1, wherein
the gate electrode is spaced apart from the first sidewall of the gate trench by a first gap,
the field distribution structure is spaced from the first sidewall of the gate trench by a second gap, and
the second gap is greater than the first gap.

3. The high voltage semiconductor device of claim 1, wherein, in a planar view, the gate electrode extends in a first direction between the first drift region and the second drift region, and the field distribution structure extends in a second direction, the second direction being an extension direction of the gate electrode.

4. The high voltage semiconductor device of claim 3, wherein the field distribution structure has a bar type shape or a ring type shape in the planar view.

5. The high voltage semiconductor device of claim 1, further comprising:
an interlayer insulating layer on the substrate and covering the first drift region, the second drift region, and the gate electrode; and
a first contact plug and a second contact plug penetrating the interlayer insulating layer and connected to the first drift region and the second drift region, respectively.

6. The high voltage semiconductor device of claim 5, wherein the field distribution structure includes a material different from a material of the gate electrode.

7. The high voltage semiconductor device of claim 6, wherein the field distribution structure includes a same material as a material of the first contact plug and a material of the second contact plug.

8. The high voltage semiconductor device of claim 6, wherein the field distribution structure has a width greater than a width of the first contact plug and a width of the second contact plug.

9. The high voltage semiconductor device of claim 5, wherein the field distribution structure includes a same material as a material of the gate electrode.

10. The high voltage semiconductor device of claim 9, wherein the field distribution structure has an upper surface lower than an upper surface of the first contact plug and an upper surface of the second contact plug.

11. The high voltage semiconductor device of claim 1, wherein a bottom level of the gate electrode is equal to or higher than a level of a lower surface of the first drift region and a level of a lower surface of the second drift region.

12. The high voltage semiconductor device of claim 1, wherein the first drift region and the second drift region cover at least portions of both corners of the bottom of the gate trench.

13. The high voltage semiconductor device of claim 1, further comprising:
a channel region,
wherein the channel region partially defined by the bottom of the gate trench in the well region, and
the channel region having an impurity concentration higher than an impurity concentration of the well region.

14. The high voltage semiconductor device of claim 1, further comprising:
a first source/drain region and a second source/drain region in the first drift region and the second drift region, respectively, and
the first source/drain region and the second source/drain region having an impurity concentration higher than an impurity concentration of the first drift region and an impurity concentration of the second drift region, respectively.

15. A high voltage semiconductor device comprising:
a substrate;
a well region of a first conductivity-type within the substrate;
a first drift region and a second drift region of a second conductivity-type arranged in the well region in a first direction;
a gate trench extending in a second direction between the first drift region and the second drift region, the second direction intersecting the first direction, and the gate trench including a bottom partially defining the well region, and a first sidewall and a second sidewall facing each other, the first sidewall and the second sidewall partially defining the first drift region and the second drift region, respectively;
a gate insulating film covering the bottom, the first sidewall, and the second sidewall of the gate trench;
a gate electrode buried in a lower region of the gate trench and extending in the second direction;
an interlayer insulating layer on the substrate and covering the first drift region, the second drift region, and the gate electrode;
a first contact plug and a second contact plug penetrating the interlayer insulating layer and connected to the first drift region and the second drift region, respectively; and
a field distribution structure penetrating the interlayer insulating layer, and extending in the second direction on the gate electrode, the field distribution structure including a same material as a material of the first contact plug and a material of the second contact plug.

16. The high voltage semiconductor device of claim 15, wherein an upper surface of the gate electrode includes a valley extending in the second direction.

17. The high voltage semiconductor device of claim 15, wherein a first side and a second side of the field distribution structure are spaced apart from the gate insulating film, and
the interlayer insulating layer has a portion filling between the first side and the second side of the field distribution structure and the gate insulating film in an upper region of the gate trench.

18. The high voltage semiconductor device of claim 15, wherein the field distribution structure has an upper surface at a same level as a level of an upper surface of the first contact plug and a level of the upper surface of the second contact plug, and the field distribution structure has a width greater than a width of the first contact plug and a width of the second contact plug.

19. A high voltage semiconductor device comprising:
a substrate;
a well region of a first conductivity-type within the substrate;
a first drift region and a second drift region of a second conductivity-type arranged in the well region in a first direction;
a gate trench extending in a second direction between the first drift region and the second drift region, the second direction intersecting the first direction, and the gate trench including a bottom partially defining the well region, and a first sidewall and a second sidewall facing each other, the first sidewall and the second sidewall partially defining the first drift region and the second drift region, respectively;
a gate insulating film covering the bottom, the first sidewall, and the second sidewall of the gate trench;
a gate electrode buried in a lower region of the gate trench and extending in the second direction;
a field distribution structure extending in the second direction on the gate electrode and having an upper surface higher than an upper surface of the first drift region and an upper surface of the second drift region, the field distribution structure including a same material as a material of the gate electrode;
an interlayer insulating layer on the substrate and covering the first drift region, the second drift region, the gate electrode, and the field distribution structure; and
a first contact plug and a second contact plug penetrating the interlayer insulating layer and respectively connected to the first drift region and the second drift region.

20. The high voltage semiconductor device of claim 19, wherein a first side and a second side of the field distribution structure are spaced apart from the gate insulating film, and
the upper surface of the field distribution structure includes a valley extending in the second direction.
